(19) United States
(12) Patent Application Publication
(10) Pub. No.: US 2015/0258636 A1
(43) Pub. Date: Sep. 17, 2015

(54) SOLDER ALLOY FOR LOW-TEMPERATURE PROCESSING

(71) Applicant: CELESTICA INTERNATIONAL INC., Toronto (CA)

(72) Inventors: Polina Snugovsky, Thornhill (CA); Simin Bagheri, Richmond Hill (CA); Marianne Romansky, Etobicoke (CA); Leonid Snugovsky, Thornhill (CA); Doug Perovic, Toronto (CA)

(73) Assignee: Celestica International Inc., Toronto (CA)

(21) Appl. No.: 14/433,168

(22) PCT Filed: Oct. 4, 2013
(86) PCT No.: PCT/CA2013/050751

§ 371 Date: Apr. 2, 2015

Related U.S. Application Data
(60) Provisional application No. 61/727,540, filed on Nov. 16, 2012.
(60) Provisional application No. 61/709,827, filed on Oct. 4, 2012.

(51) Int. Cl. B23K 35/26; H01B 1/02; H05K 3/34; B23K 35/02; C22C 13/02

(52) U.S. Cl. CPC B23K 35/262; B23K 35/025; C22C 13/02; H05K 3/3457; H05K 3/3484; H01B 1/026; H05K 2203/12; H05K 2203/041

(57) ABSTRACT

A solder composition is provided comprising from about 5.5 to 7.0 percent by weight of bismuth, from about 2.0 to 2.5 percent by weight of silver, from about 0.5 to 0.7 percent by weight of copper, and the remainder of the composition being tin. The use of the solder composition and an electronic device comprising the solder composition are also provided.

### CROSS REFERENCE TO PRIOR APPLICATIONS

This application claims priority from U.S. Provisional Patent Application No. 61/709,827 filed on Oct. 4, 2012 and U.S. Provisional Patent Application No. 61/727,540 filed on Nov. 16, 2012, the contents of each of which are hereby incorporated by reference in their entirety.

### TECHNICAL FIELD

The following relates generally to a low melting temperature solder alloy.

### BACKGROUND

Solder alloys may be used to make a permanent electrical connection between two conductors. For example, a copper wire may be soldered to a lead of a capacitor. The soldering process is typically accomplished by heating the solder to above its melting point, surrounding the leads to be connected with molten solder, and allowing the solder to cool. Solders are also used to interconnect semiconductor devices including integrated circuit chips fabricated on a silicon wafer. Typically, an array of solder bumps are deposited on the top side of the wafer, the chip is flipped such that the solder bumps align with matching pads on a substrate and the system is heated to flow the solder.

Some chips, including integrated circuit chips, may be damaged by excessive heat. Because the entire assembly is heated to flow the solder in flip chip connecting methods, the melting point of the solder must be low to prevent sensitive components from being damaged.

Historically, lead containing solders, for example, tin-lead solders, were used, as these solders have sufficiently low melting points to reduce the likelihood of damaging sensitive components. However, lead and many lead alloys are toxic. Due to increasingly strict worldwide environmental regulations, lead solders must be replaced with less toxic counterparts that also exhibit low melting points and sufficient conductivity for electronics applications.

Although some lead-free solders are known, these solders typically require processing temperatures that are 30 to 40° C. higher than those historically used for production with tin-lead solders. For example, typical lead-free solders such as SAC 305 comprising 96.5 wt % tin, 0.5 wt % copper and 3 wt % silver, have a minimum processing temperature of about 232° C., thus requiring specialized circuit board materials which can withstand these elevated temperatures. These high temperatures can thermally damage a printed circuit board (PCB) and many components attached thereto.

Furthermore, even when using circuit boards formed from specialized materials at elevated temperatures, these boards are prone to pad cratering. Pad cratering is a fracture in the resin between copper foil on the PCB and the outermost fibreglass layer of a PCB. Some of these lead-free solders also have the propensity to grow tin filament whiskers which may cause an electrical shortage, which is of particular concern in applications requiring high reliability, such as medical devices, aerospace applications, and military applications.

### SUMMARY

In one aspect, a solder composition is provided. The solder composition comprises from about 5.5 to 7.0 percent by weight of bismuth, from about 2.0 to 2.5 percent by weight of silver, from about 0.5 to 0.7 percent by weight of copper, and the remainder of the composition being tin.

In another aspect, the bismuth component is approximately equal to the silver component plus 7 times the copper component. In yet another aspect, the bismuth component is approximately 6.0 percent by weight. In yet another aspect, the silver component is 2.25 percent by weight. In yet another aspect, the copper component is 0.5 percent by weight.

In an example embodiment, the use of the solder composition on a Tg 140° C. laminate substrate is provided. In yet another aspect a circuit board comprising the solder described herein is provided. In yet another aspect, an electronic device is provided comprising the solder described herein.

### BRIEF DESCRIPTION OF THE DRAWINGS

Embodiments will now be described by way of example only with reference to the appended drawings wherein:

FIG. 1 is a differential scanning calorimetry plot of Example Composition A;

FIG. 2 is a differential scanning calorimetry plot of a lead-free solder comprising a bismuth content greater than that of Example Composition A;

FIG. 3 is a differential scanning calorimetry plot of a lead-free solder comprising a greater bismuth content and a lower silver content than those of Example Composition A;

FIG. 4 is an SEM micrograph of Example Composition A from a ball grid array (BGA) component showing thin intermetallics;

FIG. 5 is an SEM micrograph of a solder from a ball grid array component, the solder comprising 91.7% tin, 4.8% bismuth, 3.4% silver ternary alloy showing a larger grain size and thicker intermetallics when compared to FIG. 4;

FIG. 6 is an SEM micrograph of Example Composition A from a quad flat package (QFP) leaded component showing thin intermetallics;

FIG. 7 is an SEM micrograph of a solder from a QFP leaded component, the solder comprising 91.7% tin, 4.8% bismuth, 3.4% silver ternary alloy showing a larger grain size and thicker intermetallics when compared to the composition of FIG. 6;

FIG. 8 is a chart showing the thermocycling resistance of various solders in shrink small-outline package (SSOP) and BGA test samples;

FIG. 9 is an accelerated temperature cycling (ATC) chart showing temperatures over several periods of thermocycling resistance testing;

FIG. 10 is an x-ray image showing voiding in an example BGA component assembled using SAC 305 solder on an organic solderability protection (OSP) surface;

FIG. 11 is an x-ray image showing voiding in an example BGA component assembled using Example Composition A solder on an OSP surface;

FIG. 12 is a photograph showing wetting of SAC 305 solder on an OSP surface of a QFP component;

FIG. 13 is a photograph showing wetting of Example Composition A solder on an OSP surface of a QFP component;

FIG. 14 is a micrograph of an example BGA component assembled using SAC 305 solder on an OSP surface;

FIG. 15 is a micrograph of an example QFP component assembled using SAC 305 solder on an OSP surface;

FIG. 16 is a micrograph of an example BGA component assembled using Example Composition A solder on an OSP surface;

FIG. 17 is a micrograph of an example QFP component assembled using Example Composition A solder on an OSP surface;

FIG. 18A is a SEM micrograph showing the microstructure of an example BGA joint assembled using SAC 305 on an OSP surface;

FIG. 18B is a SEM micrograph showing the microstructure of an example BGA joint assembled using SAC 305 on an electroless nickel immersion gold (ENIG) surface;

FIG. 18C is a SEM micrograph showing the microstructure of an example BGA joint assembled using Sn3.4% Ag4.8% Bi solder on an OSP surface;

FIG. 18D is a SEM micrograph showing the microstructure of an example BGA joint assembled using Sn3.4% Ag4.8% Bi solder on an ENIG surface;

FIG. 18E is a SEM micrograph showing the microstructure of an example BGA joint assembled using Sn3.4% Ag4.8% Bi solder on an electroless nickel electroless palladium immersion gold (ENEPIG) surface;

FIG. 18F is a SEM micrograph showing the microstructure of an example BGA joint assembled using Example Composition A on an OSP surface;

FIG. 18G is a SEM micrograph showing the microstructure of an example BGA joint assembled using Example Composition A on an ENIG surface;

FIG. 18H is a SEM micrograph showing the microstructure of an example BGA joint assembled using Example Composition A on an ENEPIG surface;

FIG. 19A is a SEM micrograph showing the microstructure of an example QFP joint assembled using SAC 305 on an OSP surface;

FIG. 19B is a SEM micrograph showing the microstructure of an example QFP joint assembled using SAC 305 on an ENIG surface;

FIG. 19C is a SEM micrograph showing the microstructure of an example QFP joint assembled using Sn3.4% Ag4.8% Bi solder on an OSP surface;

FIG. 19D is a SEM micrograph showing the microstructure of an example QFP joint assembled using Sn3.4% Ag4.8% Bi solder on an ENIG surface;

FIG. 19E is a SEM micrograph showing the microstructure of an example QFP joint assembled using Sn3.4% Ag4.8% Bi solder on an ENEPIG surface;

FIG. 19F is a SEM micrograph showing the microstructure of an example QFP joint assembled using Example Composition A on an OSP surface;

FIG. 19G is a SEM micrograph showing the microstructure of an example QFP joint assembled using Example Composition A on an ENIG surface; and

FIG. 19H is a SEM micrograph showing the microstructure of an example QFP joint assembled using Example Composition A on an ENEPIG surface.

### DETAILED DESCRIPTION

A low melting temperature solder alloy is provided. The alloy is a lead-free quaternary tin-silver-bismuth-copper alloy. The solder alloy comprises 5.5 to 7.0 percent by weight of bismuth, 2.0 to 2.5 percent by weight of silver, 0.5 to 0.7 percent by weight of copper, and the remainder being tin.

In one aspect, the composition of the solder described herein is governed by the following relationship within the above-specified composition ranges:

% Bi=% Ag+7×(% Cu)

For example, if the silver component is 2.25 wt % and the copper component is 0.5 wt %, the bismuth component is 5.75 wt % according to the above relationship. This relationship of elemental composition in the quaternary alloy has been discovered to be surprisingly advantageous. It will be appreciated that a slight variation from the above relationship of about ±0.3 wt % in bismuth content will be deemed to be generally acceptable for most applications.

In one aspect, a solder composition is provided consisting essentially of from about 5.5 to 7.0 percent by weight of bismuth, from about 2.0 to 2.5 percent by weight of silver, from about 0.5 to 0.7 percent by weight of copper, and the remainder of the composition being tin.

As used herein, the phrase “consisting essentially of” will be understood to mean that the solder composition described using this phrase will be limited to specific materials recited following the phrase and those that do not materially affect the basic and novel characteristic(s) of the solder composition. For example, it will be appreciated that various solder compositions may contain different trace elements that do not materially affect the basic characteristics of these solder compositions.

In Example Composition A, the solder comprises 6 percent by weight of bismuth, 2.25 percent by weight of silver, 0.5 percent by weight of copper, and the balance being tin.

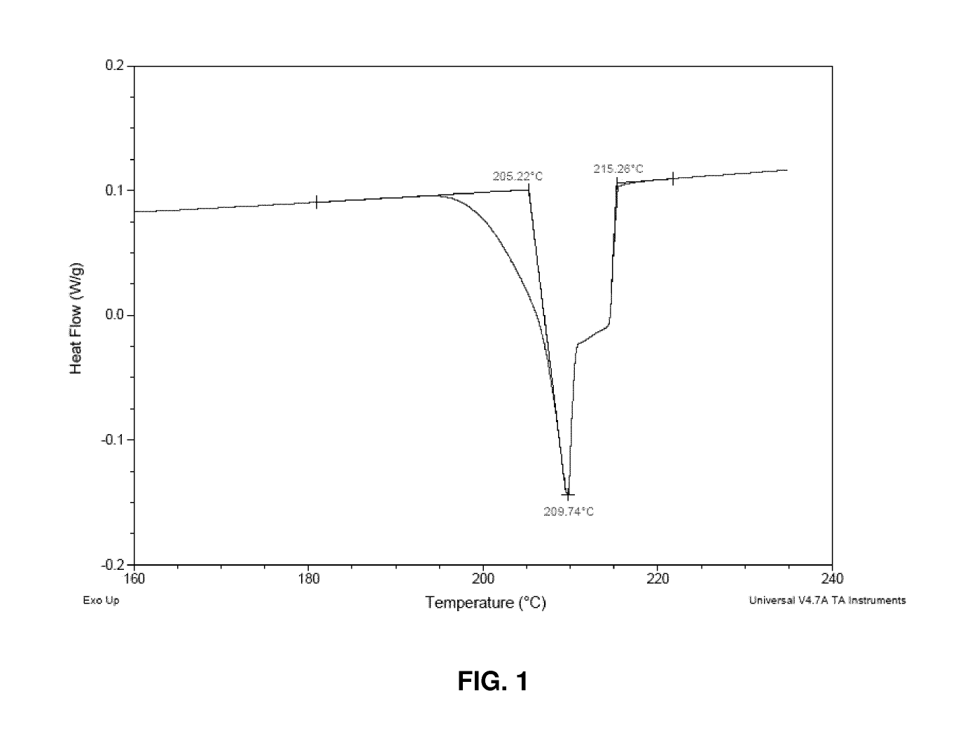

Turning to FIG. 1, the Example Composition A alloy exhibits a melting point of as low as approximately 205° C., as measured using differential scanning calorimetry (DSC). The plot of FIG. 1 was generated by heating the example solder composition at 2° C. per minute from 120 degrees to 235° C. As can be seen from the plot of FIG. 1, the sample begins melting at approximately 205° C. and becomes fully melted at approximately 215° C. At temperatures between 205 and 215° C., the solder is in what is referred to as the “pasty range”. A narrower pasty range is typically preferred for soldering ball grid array (BGA) and leaded components such as quad flat package (QFP), since a wide pasty range may allow the solder joint to open before solidifying, thus potentially causing the solder joint to fail. The pasty range may also be calculated by taking the difference between the solidus temperature and the liquidus temperature, which are generally measured using a DSC.

A bismuth content of about 6.0 wt % provides the narrowest pasty range. As such, a solder comprising 6.0 percent by weight of bismuth such as Example Composition A has favourable processing characteristics. When the bismuth component is increased to substantially more than 7.0 wt % or decreased to below 5.5 wt %, the pasty range widens, rendering the processing characteristics of the solder less favourable and leaving joints prone to opening.

The example solder of FIG. 1 exhibits a processing temperature of approximately 220 to 226° C. A processing temperature of approximately 220 to 226° C. is similar to the processing temperatures used for lead-based solders. As such, many of the materials developed for temperatures sustained by lead-based solders may be used in conjunction with the solder described herein. Processing at these temperatures rather than at about 232° C. or above preferably allows the use of standard board laminate materials, which have a lower likelihood of pad cratering failures and also reduce the risk of damaging temperature-sensitive components. It is understood that, conventionally, the processing temperature of a solder is higher than the liquidus temperature to ensure that the solder is fully melted to achieve better wetting.

The solder may exhibit improved thermo-mechanical properties and increased mechanical resistance to shock. Specifically, the bismuth component reduces the melting temperature and improves thermo-mechanical properties as will be described below.

The solder composition provided may be characterized by a reduced propensity to grow tin filament crystal whiskers. By mitigating or preventing whisker growth, the reliability of boards and systems may be improved in comparison to manufacturing processes using SAC 305 or SAC 105. SAC 105 comprises 98.5 wt % tin, 1 wt % silver, and 0.5 wt % copper. SAC 305 comprises 96.5 wt % tin, 0.5 wt % copper and 3 wt % silver. Specifically, the propensity for whiskers to form is significantly reduced when the bismuth component is at least 5.0% of the solder composition by weight. The reduced silver content, in combination with the bismuth component, may also aid in mitigating whisker formation and reducing the melting temperature of the alloy. It is noted that neither SAC 105 nor SAC 305 contain bismuth.

The solder composition described herein may be used in electronics assembly of leaded and leadless components as well as with BGA components. Furthermore, the above-described alloy is compatible with SAC 305 and SAC 105. Even when the solder is mixed with SAC 305 or SAC 105 solder balls in BGA's or chip scale packaging (CSP), the solder composition may comprise enough bismuth to depress the melting temperature of the solder and to improve the thermo-mechanical properties of the solder. This has been confirmed using Example Composition A in BGA applications having 25 mil SAC 305 spheres. It was determined that a solder paste having a volume of about at least 15% of the volume of the sphere may exhibit improved thermo-mechanical properties. Preferably, in BGA processing, the solder volume is at least about 20% of the volume of the sphere to improve the thermo-mechanical properties of the resulting solder interconnect. According to one embodiment, the solder composition described herein may be used to solder a surface mount component to a circuit board by first covering the contact pads of the circuit board with a solder paste. The surface mount component is then positioned over the circuit board and aligned with respect to the appropriate contact pads. Once the component is aligned, it is lowered until the terminals of the surface mount component are in contact with the solder paste covering the contact pads. The terminals may be, for example, leads in the case of a QFP or solder balls in the case of a BGA. The assembly is then heated to the processing temperature to melt the solder, thus causing the component to be soldered onto the circuit board.

The processing temperature for these processes may be as low as about 220° C. to about 222° C., which is very similar to conventional lead solder processing temperatures.

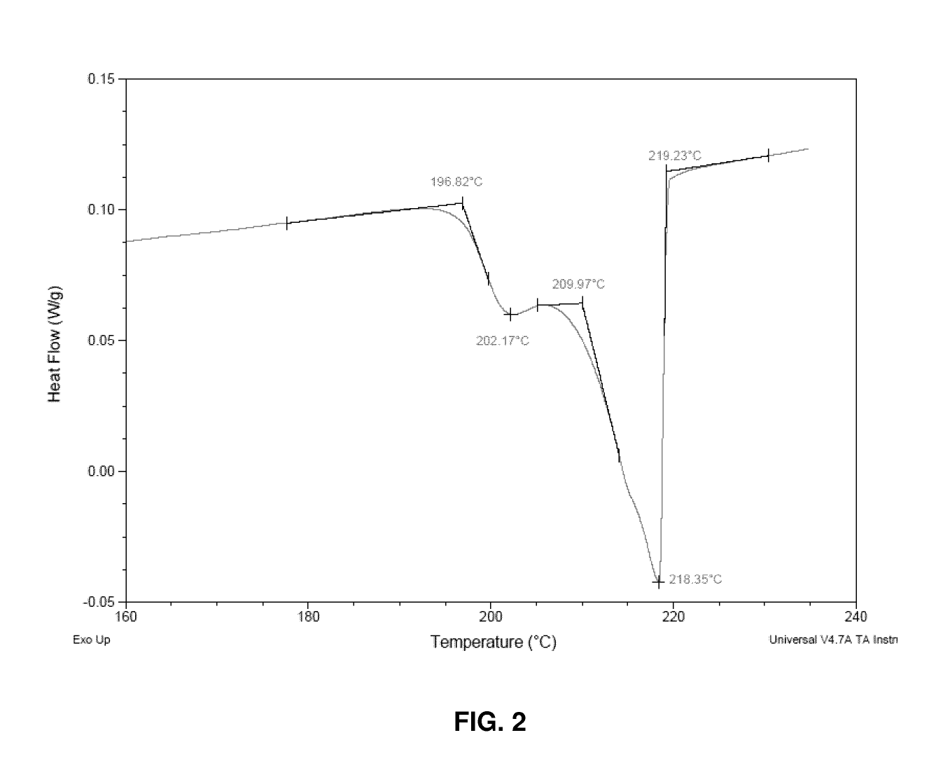

Turning to FIG. 2, a DSC plot for a solder composition comprising 2.0 wt % silver, 0.5 wt % copper, 7.5 wt % bismuth and 91.0 wt % tin, hereinafter “Example Composition B”, is provided for comparative purposes. Similarly to the plot of FIG. 1, the plot of FIG. 2 was generated by heating the example solder composition at 2° C. per minute from 120 degrees to 235° C. It will be appreciated that the silver and copper components of this solder composition fall within the above-noted range for the solder described herein, however, the bismuth component is 0.5% higher than the maximum allowed. As such, Example Composition B is used to illustrate the effects of increasing the bismuth component to higher than approximately 7.0%.

As can be seen from the DSC plot, the solder begins melting at approximately 197° C. and, as such, is characterized by a lower melting initiation point than Example Composition A. However, it can also be seen from FIG. 2 that the solder is not fully melted until it reaches a temperature of about 219° C. Hence, the pasty range of this solder, which spans about 22° C., is wider than the pasty range of the Example Composition A, which spanned only about 10° C. As such, by limiting the bismuth component to about 7% or lower, the pasty range of the solder can be reduced, thereby improving processing characteristics of the solder.

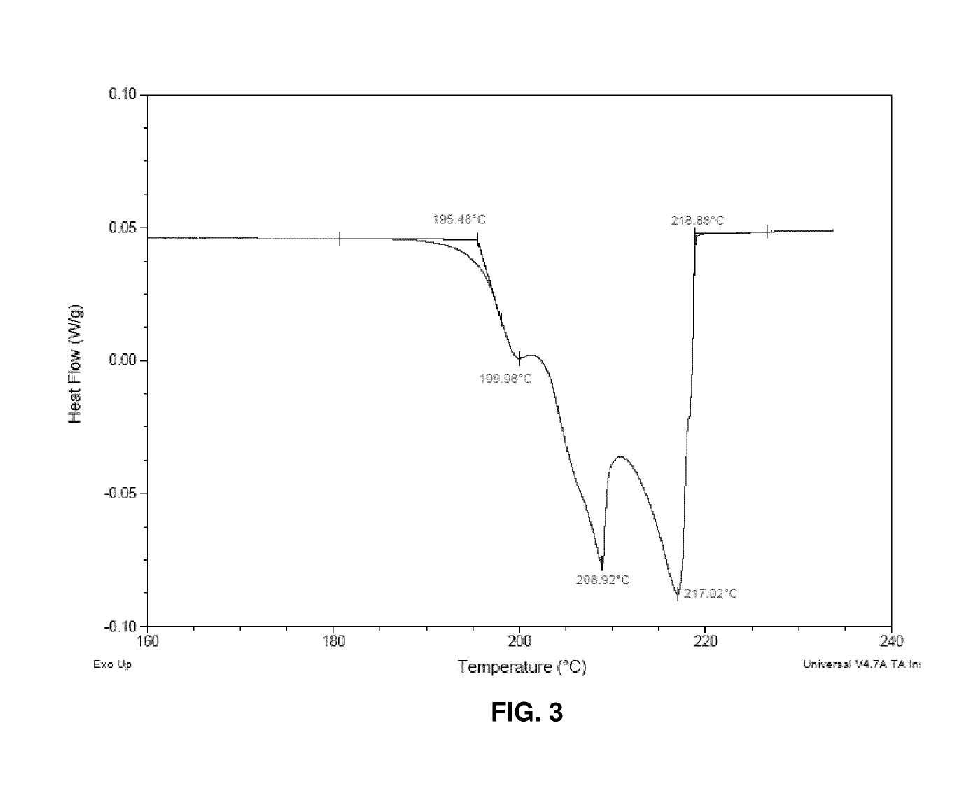

Similarly, FIG. 3 is a DSC plot of an alloy comprising 1.5 percent by weight of silver, 0.7 percent by weight of copper, 7.5 percent by weight of bismuth, and the remainder being tin. The DSC data was obtained using the same procedures as above. Similarly with the DSC plot of FIG. 2, the increase in the bismuth content causes a widening of the pasty range. The reduction in silver content from 2.0 percent to 1.5 percent causes a slight broadening of the pasty range.

Mechanical resilience of solder joints, in particular drop resistance, may depend on whether a brittle intermetallic exists within the solder joint. Intermetallic species present in solder joints typically form when the solder alloy is cooled from its molten state. For example, a tin-bismuth-copper alloy may form a brittle Cu₆Sn₅ intermetallic upon cooling if the copper content is above the eutectic composition. It is therefore important to ensure that the copper content is sufficiently low to prevent brittle intermetallic species from forming in a solder joint.

Due to the relatively low melting point of the solder alloy composition with respect to other lead-free solder compositions, the solder alloy provided is more compatible with heat sensitive parts. The solder alloy is characterized by a minimum processing temperature of approximately 222° C. The minimum processing temperature is sufficient for soldering components with leads, also known as “leaded components”, as well as ball grid array connections. Leaded components typically comprise tin on the immediate soldering surface, with copper or other alloys also contributing to the solder joint. The low melting temperature of the solder composition may reduce overheating during solder processing steps. Additionally, the lower soldering temperature and narrow pasty range relative to conventional lead free solders may reduce circuit board mechanical failure modes such as delamination, warpage, and open solder joints, also known as head-in-pillow.

The low melting point of the solder may enable the use of circuit board materials and other electronic components that are less heat-resistant, as these materials and components are typically less brittle at room temperature. For example, the solder composition provided herein may be used with laminate boards having a glass transition temperature of 140° C., also known as Tg 140° C. laminates.

Tg 140° C. laminates are well established within the electronics industry and the performance of the boards with respect to soldering temperature is well characterized. Tg 140° C. laminates are generally reliable in electronics products, as these laminates are less brittle and less susceptible to the pad cratering failure mode, which is a mechanically-induced fracture in the resin of the laminate between the outermost layer of fibreglass and copper foil. In contrast, materials typically used in standard lead-free processes have a higher glass transition temperature of 170° C. and are known as Tg 170° C. laminates. The low melting point of the solder reduces production costs, as Tg 140° C. circuit boards are less expensive than Tg 170° C. circuit boards.

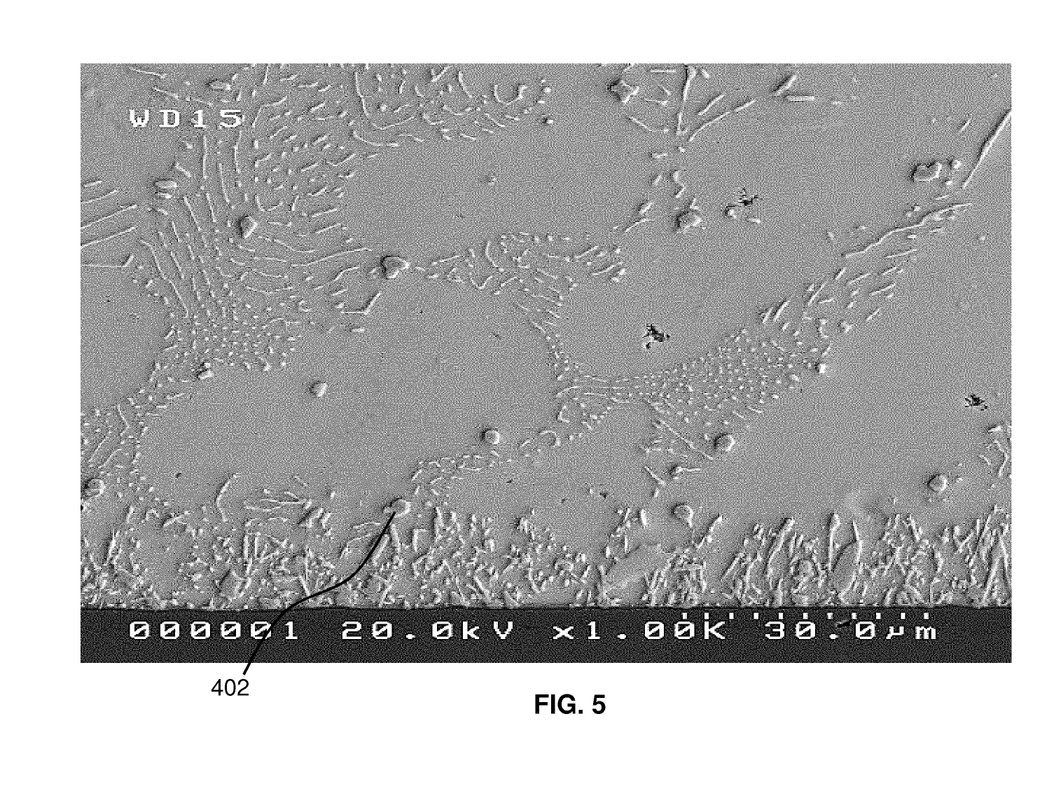

In addition to processing temperature, the microstructures of solder alloys and joints formed using such alloys are of importance, as the microstructure may have an effect on the thermo-mechanical and electrical properties of a solder. Slight variations in the mass percent of each of the constituent elements in a solder alloy may have an appreciable effect on the structure and the melting temperature of the alloy. Copper is included in the solder alloy described herein to suppress dissolution of copper from copper surfaces that the solder is contacting during processing steps. For example, the solder may dissolve a portion of a copper pad. By suppressing dissolution of copper surfaces, the likelihood of formation of excess interfacial intermetallics such as those shown in FIG. 5 is reduced.

The solder composition described herein is near-eutectic with respect to the copper component. A near-eutectic composition is a composition that is near the eutectic line. In this case, the copper component is slightly below the eutectic line. If the copper content of the solder composition were increased to 0.8 wt % or above, the solder composition may rise to the hypereutectic range.

If the solder composition is hypereutectic, the solder will form brittle intermetallic species such as Cu₃Sn and Cu₆Sn₅. It is therefore important to ensure that the solder composition is eutectic or slightly hypoeutectic when cooling. Importantly, if the solder alloy is cooled very quickly, it is possible that brittle intermetallic species could form even in a hypoeutectic composition. It is for this reason that in most applications where the cooling rate of the solder cannot be practically controlled, a solder having a slightly hypoeutectic composition may be used.

When the solder is heated to its molten state and brought in contact with a copper surface, the solder may dissolve a portion of the copper surface. The dissolved copper enters into the solder composition, thereby increasing the weight percent composition of copper in the solder alloy. Therefore, for applications where the molten solder will come in contact with copper, it is important that the solder composition is hypoeutectic to account for the solubilised copper during the soldering process. The percent composition of copper in the alloy may be varied depending on the intended use of the solder. For example, when soldering two copper contacts, it may be desirable to use a solder composition with a lower copper content, for example, 0.5 wt % Cu. Conversely, when soldering other metal contacts, it may be desirable to have a solder composition with a comparatively high copper content, for example, 0.7 wt % Cu.

As outlined above, below a composition of 2 wt % silver, the pasty range of this quaternary alloy increases and the favourable thermo-mechanical properties of the alloy decrease. Above a composition of about 2.5 wt % silver, silver-tin intermetallics begin to form. Silver-tin intermetallics may reduce the mechanical strength of the solder alloy. For example, intermetallics may be a point of crack initiation, thereby reducing the solder's ability to withstand high mechanical stresses or cyclic mechanical stresses.

A solder composition comprising 5.5 to 7.0 percent by weight of bismuth, 2.0 to 2.5 percent by weight of silver, 0.5 to 0.7 percent by weight of copper, and the remainder being tin typically reduces the growth of large intermetallic grains in the solder alloy. Specifically, a bismuth component of at least 5 wt % reduces the propensity for whisker formation and reduces the size of intermetallics, however, as previously mentioned, bismuth contents below 5.5% generally give rise to wider pasty ranges and are therefore unfavourable.

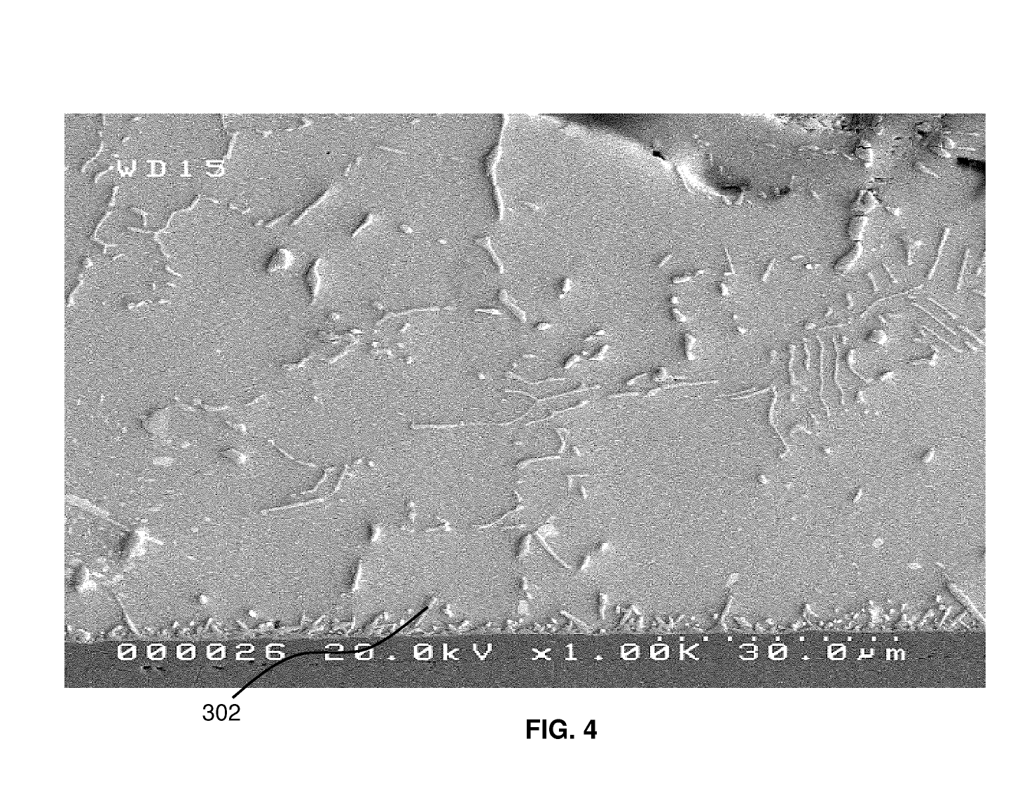

FIG. 4 and FIG. 5 are scanning electron microscope (SEM) micrographs of the polished surface of ball grid array component sections. The composition of the solder alloy of FIG. 4 is that of Example Composition A, whereas the solder alloy of FIG. 5 comprises 3.4 wt % silver, 4.8 wt % bismuth, and the remainder tin.

The solder alloy of FIG. 4 has thinner intermetallics with smaller grain sizes when compared with the intermetallics visible in FIG. 5. Intermetallics may have the most influence on a solder joint when they are located at an interface. The representative interface intermetallic of FIG. 4 highlighted by numeral 302 is far thinner and of a smaller grain size when compared to the representative interface intermetallic of FIG. 5, highlighted by numeral 402. A limited number of thin intermetallics may be beneficial for mechanical properties at the interface. However, large, thick intermetallics have a deleterious effect on the mechanical properties of solder joints.

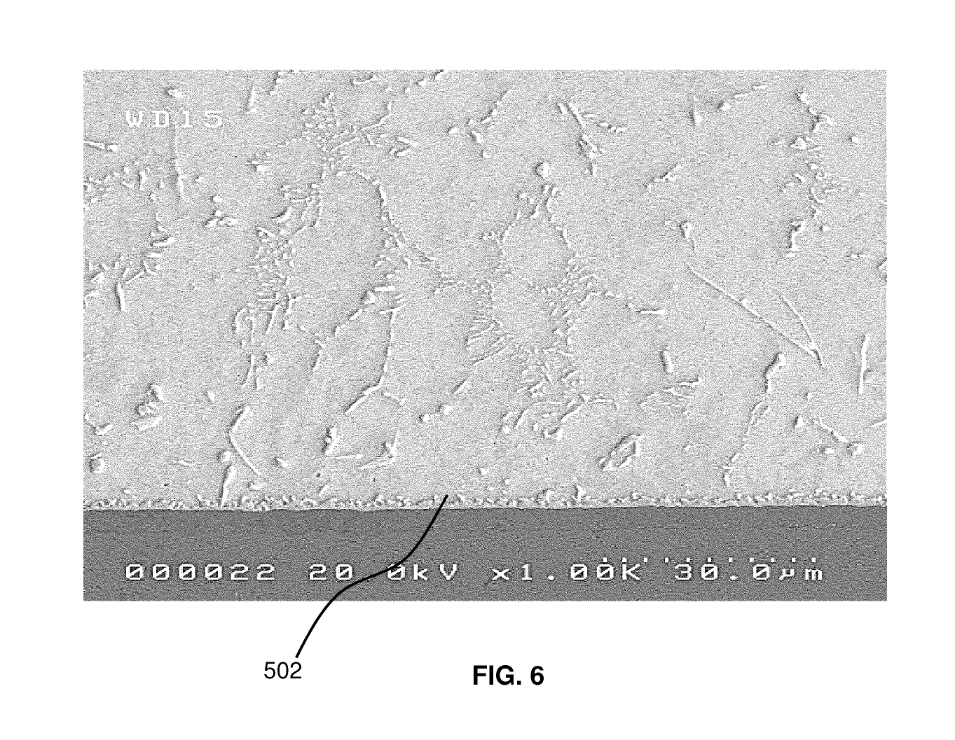

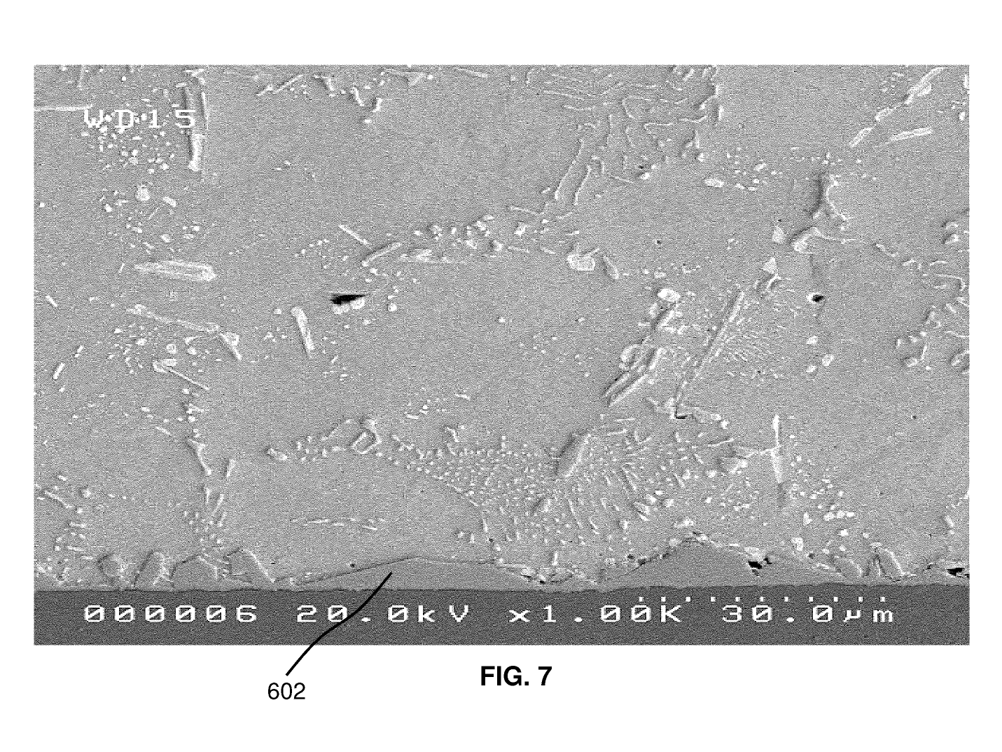

FIG. 6 and FIG. 7 are SEM micrographs of the polished surface of leaded component sections from a quad flat pack (QFP). The solder alloys of FIG. 6 and FIG. 7 are identical to those of FIG. 4 and FIG. 5, respectively. As is highlighted by reference numeral 502 in FIG. 6, the intermetallics of the solder composition of Example Composition A are thinner and exhibit smaller grain sizes than the intermetallics of the sample comprising 3.4 wt % silver, 4.8 wt % bismuth and the remainder being tin. In particular, in FIG. 7, the intermetallic on the interface, highlighted by numeral 602, is significantly thicker and exhibits a much larger grain size. Furthermore, in FIG. 7, the intermetallics are shown as accumulating at the solder-pad interface (i.e. board side interface). Although large intermetallic grains anywhere in a solder joint are generally undesirable, large intermetallic grains near or at an interface are particularly disadvantageous. It can be seen that the solder alloy described herein advantageously has thinner intermetallics with smaller grain sizes both distributed within the BGA and QFP joints as well as at the interfaces. It is noted that the formation of copper-nickel intermetallics 602 shown in FIG. 7 at the board side interface is the result of copper from the QFP leads rapidly dissolving into the solder and then quickly diffusing through the bulk solder to reach the board side interface. Here, the fast diffusion of copper is driven by the chemical potential difference between the lead and the solder. In FIG. 6, the additional copper in the solder alloy suppresses the formation of intermetallics when compared to sample shown in FIG. 7, due to the lower chemical potential difference between the lead and the solder.

A chart of the intermetallic thickness with respect to the solder composition and surface type is provided in Table 1. As will be appreciated from Table 1, the intermetallic thickness for solder joints comprising Example Composition A is comparable in size to the intermetallic thickness for solder joints comprising SAC 305 and 91.7 wt % Sn, 4.8 wt % Bi and 3.4 wt % Ag. The electroless nickel-electroless palladium-immersion gold (ENEPIG) surface was prepared with an approximately 3.8 micron nickel layer, a 50 nm palladium layer and an 80 nm gold layer. Although the intermetallic thickness for Example Composition A on electroless nickel-immersion gold (ENIG) surface is slightly larger than equivalent joints using SAC 305, they are sufficiently close in size and within an acceptable range for many applications. In particular, the example ENIG surface was prepared with an approximately 3.8 micron nickel layer and an approximately 130 to 200 nm gold layer. It is also worthy of note that solder joints comprising Example Composition A have relatively uniform intermetallic thicknesses across all the surface finishes for the QFP joints. For further clarity, intermetallics formed at the interface between the solder and the circuit board surface finish is referred to as “board side” and intermetallics formed at the interface between the solder and the component surface finish, or in the case of a BGA, the solder ball, is referred to as “component side” in Table 1. The thicknesses were measured by analyzing the cross-sectional images of solders acquired using a scanning electron microscope (SEM).

TABLE 1
Intermetallic Thicknesses of Various Solders on OSP, ENIG, and ENEPIG Surfaces

| | | QFP Intermetallic | | BGA Intermetallic | |
|---|---|---|---|---|---|
| | | Thickness (μm) | | Thickness (μm) | |
| | Surface | | Component | | Component |
| Solder Name | finish | Board Side | Side | Board Side | Side |
| SAC305 | OSP | 2.1 | 2.5 | 3.3 | 2.4 |
| 91.7% Sn, 4.8% Bi, | OSP | 1.9 | 1.9 | 2.4 | 1.5 |
| 3.4% Ag | | | | | |
| Example Comp. A | OSP | 1.9 | 2.2 | 2.1 | 1.7 |
| SAC305 | ENIG | 1.2 | 2.3 | 1.6 | 1.4 |
| 91.7% Sn, 4.8% Bi, | ENIG | 2.1 | 3.6 | 1.0 | 1.3 |
| 3.4% Ag | | | | | |
| Example Comp. A | ENIG | 1.7 | 2.6 | 2.1 | 1.2 |
| 91.7% Sn, 4.8% Bi, | ENEPIG | 1.5 | 3.5 | Irregular, | 1.7 |
| 3.4% Ag | | | | Large | |
| Example Comp. A | ENEPIG | 1.8 | 2.1 | 1.1 | 0.9 |

The effect of intermetallics on solder joint properties depends not only on the sizes of the intermetallics but also on the composition of the intermetallics. For example, the intermetallic reaction layer formed between nickel and gold finished component pads and the SAC305 solder ball was substantially found to be a ternary compound containing about 20 to 25 atomic % Ni, 30 to 35 atomic % Cu, and 42 to 45 atomic % Sn. The ternary compound may correspond to the formula Ni₂₃Cu₃₃Sn₄₄. This type of intermetallic forms on ENIG and ENEPIG finished boards when soldered using SAC305 or Example Composition A. Ni₂₃Cu₃₃Sn₄₄ provides a smoother morphology than some other intermetallics such as (Ni,Cu)₃Sn₄, which has a sharper, needle-like morphology. Generally, formation of intermetallics having smooth morphologies is advantageous in terms of mechanical properties, as they provide fewer stress concentrators.

The formation of favorable interfacial intermetallic layers in solder joint is important for applications in harsh environments. The intermetallic may form metallurgical bonds with common basis materials found in the surface finish. For example, the base material may be copper, or nickel in the case of an ENIG or ENEPIG surface finish. If a solid thin layer of intermetallics is formed, the intermetallics may have a strengthening effect on solder joints. However, if the interfacial intermetallic layers are too thick, these layers may cause joint embrittlement.

Furthermore, the resistance characteristics of solder interconnections may differ between thermal cycling stress and shock impact stress (e.g. from a drop-test). Generally, the strain-rate (i.e. the change in strain over time) increases as the stresses in solder interconnections increase. Typically, shock impact stress is much higher than thermal cycling stress. As such, the intermetallic compound layers will experience significantly higher stresses in a shock test when compared to those experienced during thermal cycling. Hence, the properties of intermetallic layers may play a comparatively larger role in the reliability of the solder joint when the joint is subjected to shock impact. The fracture toughness of solder joints may decrease rapidly with increasing intermetallic reaction layer thickness. Therefore, the interfacial intermetallic thickness and morphology should be carefully controlled to maximize shock resistance. In Example Composition A, controlling the interfacial intermetallic thickness has been found to improve shock resistance.

It will be appreciated that although the above is explained with reference to intermetallics, the composition of Example Composition A, or, more generally, any composition comprising 5.5 to 7.0 percent by weight of bismuth, 2.0 to 2.5 percent by weight of silver, 0.5 to 0.7% by weight of copper and the remainder being tin will exhibit a reduced propensity for whisker growth and thus, a reduced likelihood of shorts when soldering components. For example, QFP components often have leads separated by approximately 0.4 mm. Whisker growth emanating from solders on each of the leads may cause a short between leads, leading to failure or malfunction of the component. As such, a solder having a reduced propensity for whisker growth is advantageous.

Furthermore, the morphology of the alloy shown in FIG. 4 and FIG. 6 may be favourable in terms of mechanical properties including drop shock resistance. Typically, large brittle intermetallic Cu₆Sn₅ and Cu₃Sn species such as those shown, for example, using reference numeral 602 in FIG. 7, compromise the mechanical integrity of the solder. Silver-tin intermetallics, for example, Ag₃Sn may also form. Large Ag₃Sn platelets may embrittle the solder, thereby reducing the solder's vibration and thermo-mechanical characteristics.

Specifically, the surface of the solder alloy on the interface with the intermetallic crystals 602 is a possible location of crack initiation, particularly if a component comprising such a solder joint is subject to large stresses, for example, from being dropped on a hard surface. Since it is likely that the stress intensity factor at the interface between the intermetallic crystal 602 and the solder alloy will be greater than that of the bulk alloy, the area around the intermetallic crystals may also be more susceptible to crack propagation from repeated stresses or impacts in comparison to the bulk material. As such, by reducing the size and thickness of intermetallics, mechanical properties of a solder alloy may be enhanced.

The silver component in the Example Composition A may provide the solder with a higher thermocycling resistance and a higher vibration resistance. This may be at least partially attributed to the reduced propensity for growth of embrittling intermetallics such as Ag₃Sn platelets. To determine the thermocycling resistance of Example Composition A, a number of test boards were produced, some comprising SAC 305 solder paste for comparative purposes and others comprising Example Composition A solder paste. A peak reflow temperature of 240° C. was used to produce the SAC305 solder whereas a lower peak reflow temperature of 222° C. was used to produce Example Composition A solder. The time above liquidus was approximately 70 to 90 seconds in each case. Analysis Tech STD-256 event detectors were used to monitor the resistance thresholds of components on each of the boards. Failure was recorded when the channel resistance exceeded 300Ω for at least 200 ns.

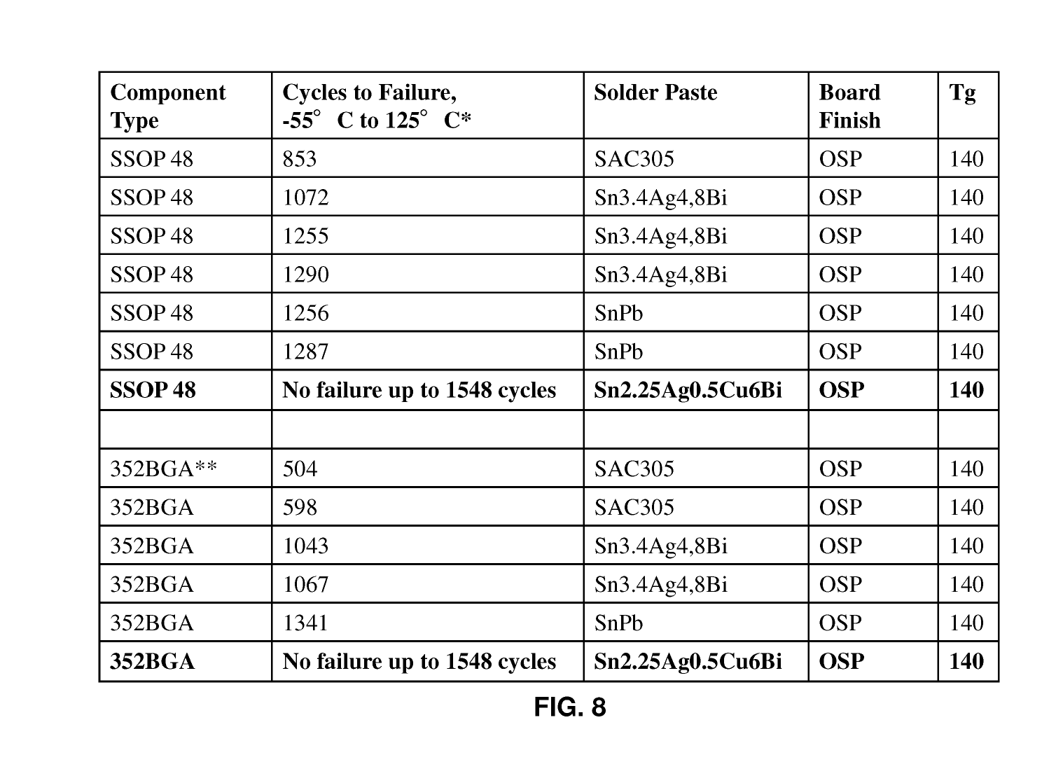

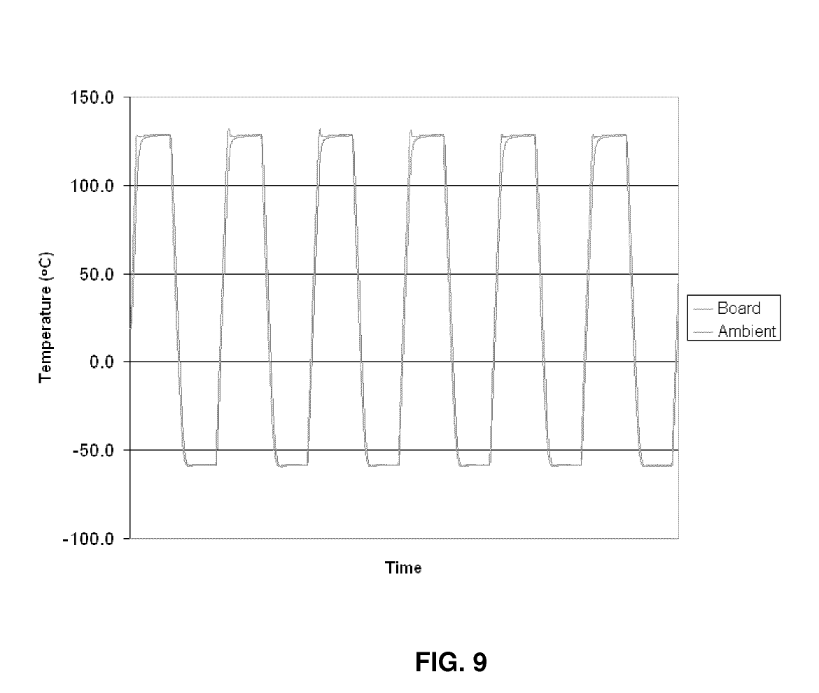

Referring now to FIG. 8, a table comparing the number of cycles to failure is provided for various components assembled with different solder paste samples. The tests were performed by cycling the temperature of assemblies of ball grid array (terminated with SAC305 balls) and shrink small-outline package (SSOP) components between −55° C. and 125° C. A ramp rate of 10° C./min and a dwell time of 30 minutes at both temperature extremes were used to conduct the temperature cycling. Several periods of the accelerated temperature cycling (ATC) profile are shown in FIG. 9.

As a reference, aerospace applications typically require components to last at least 1000 cycles prior to failure. As is clear from the table, the SAC305 was the least thermo-mechanically robust, failing after only 853 cycles for the SSOP sample and barely more than 500 cycles for the BGA sample. The samples using tin-lead solders survived more than 1250 cycles for SSOP and over 1300 cycles for BGA. The Sn3.4Ag4.8Bi soldered samples also survived approximately over 1050 cycles prior to failure in both SSOP and BGA devices. However, the component soldered using Example Composition A exhibited no failure up to almost 1550 cycles for the SSOP and BGA samples. As will be appreciated, this increase in thermo-mechanical resistance may be important for critical applications, for example, in aerospace applications.

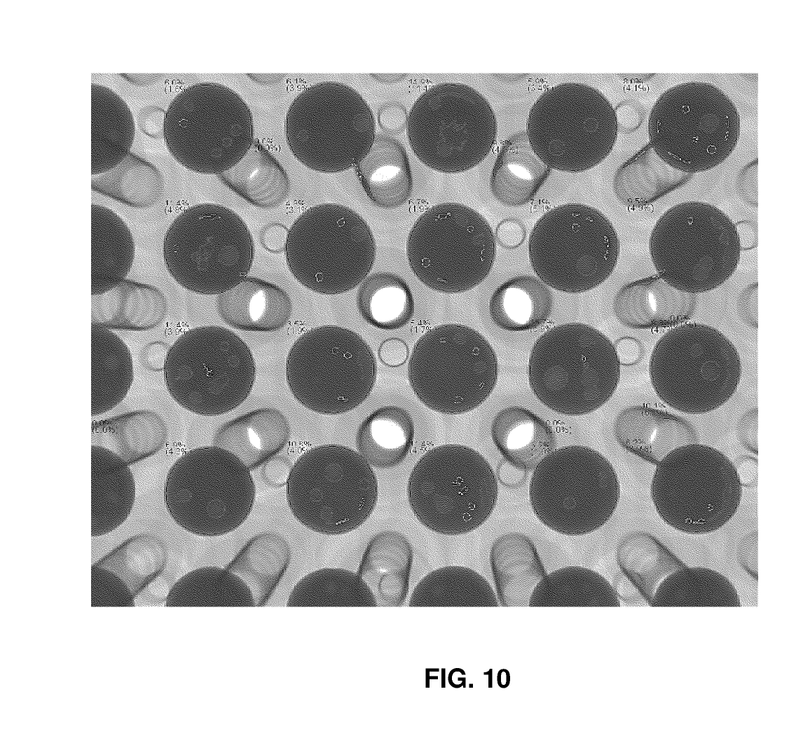

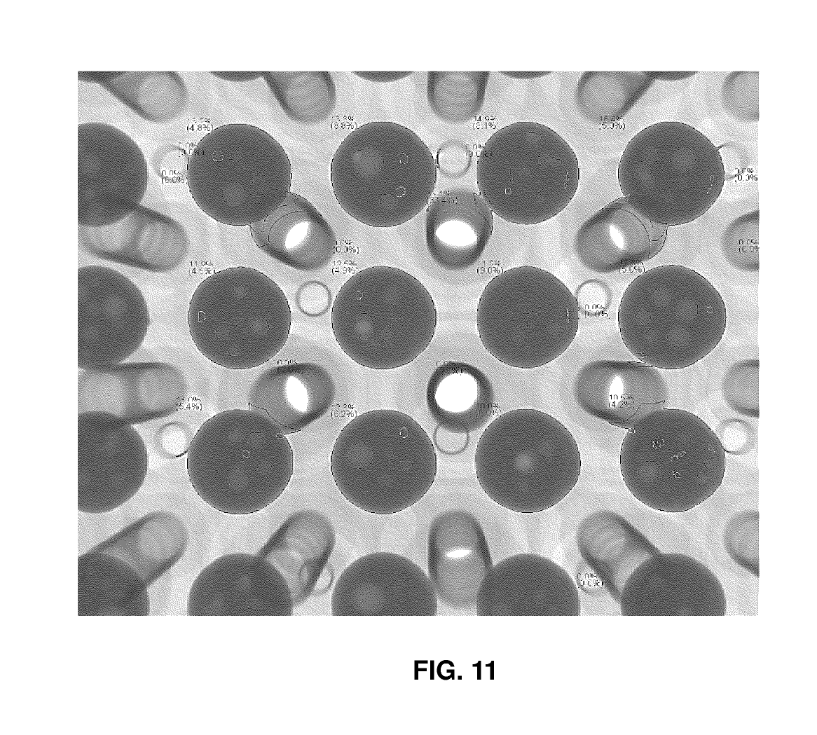

As mentioned above, Example Composition A may exhibit an improved vibration resistance when compared with SAC 305. It has also been found that Example Composition A may form acceptable solder joints in terms of voiding, wetting, shape, and size. FIGS. 10 and 11 are x-ray images of BGA joints formed with SAC 305 solder and Example Composition A, respectively. As will be appreciated from the highlighted portions of these figures, Example Composition A has no more voiding than SAC 305, measured by volume. In fact, Example Composition A was found to have 22% by volume voiding on organic solderability protection (OSP) surfaces whereas SAC 305 was found to have 24.5% voiding by volume. Similarly, for ENIG surfaces, Example Composition A showed 12.1% voiding whereas SAC 305 showed 23.2% voiding, both measured by volume. Example Composition A also exhibited low voiding on ENEPIG surfaces of 3.5% by volume.

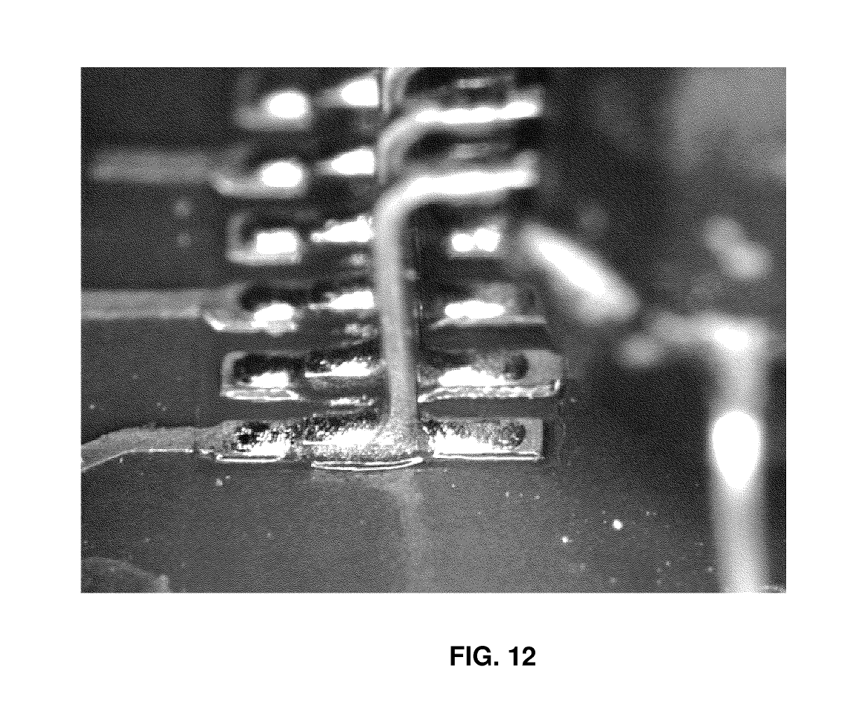

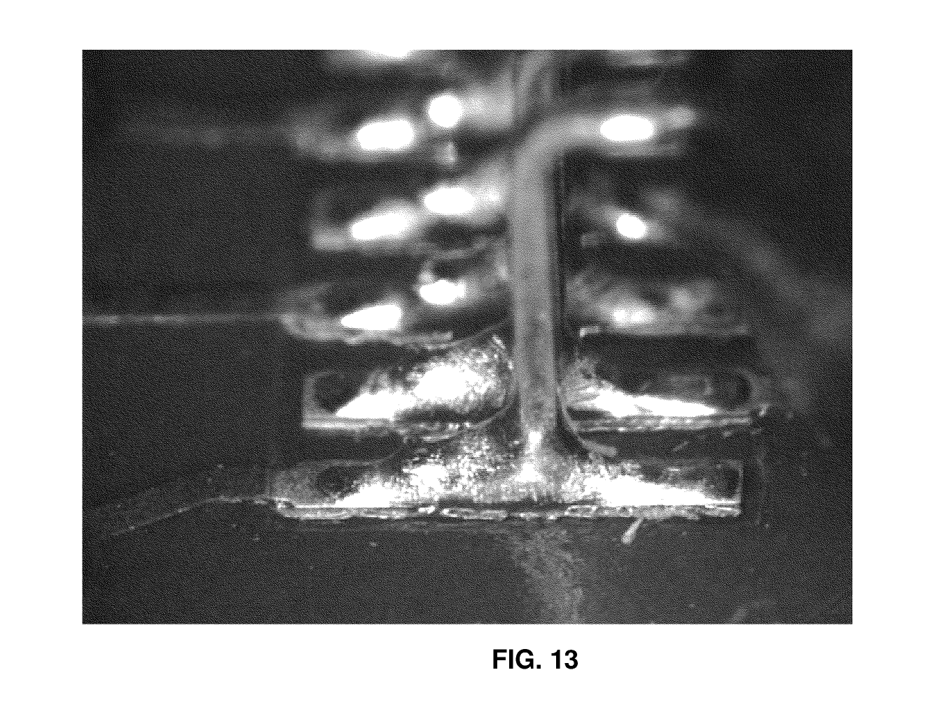

The wetting characteristics of Example Composition A were also found to be favourable. Turning to FIG. 12, a reference QFP solder joint on an OSP surface is shown using SAC 305. FIG. 13 shows a QFP solder joint on an OSP surface using Example Composition A. As will be appreciated from FIG. 13, the wetting characteristics of the solder are favourable for forming QFP joints on OSP surfaces. This is illustrated by the fact that the majority of the conductive pads are covered (i.e. wetted) by the solder in FIG. 13. Example Composition A has also been found to exhibit favourable wetting characteristics on other surfaces such as ENIG and ENEPIG surfaces.

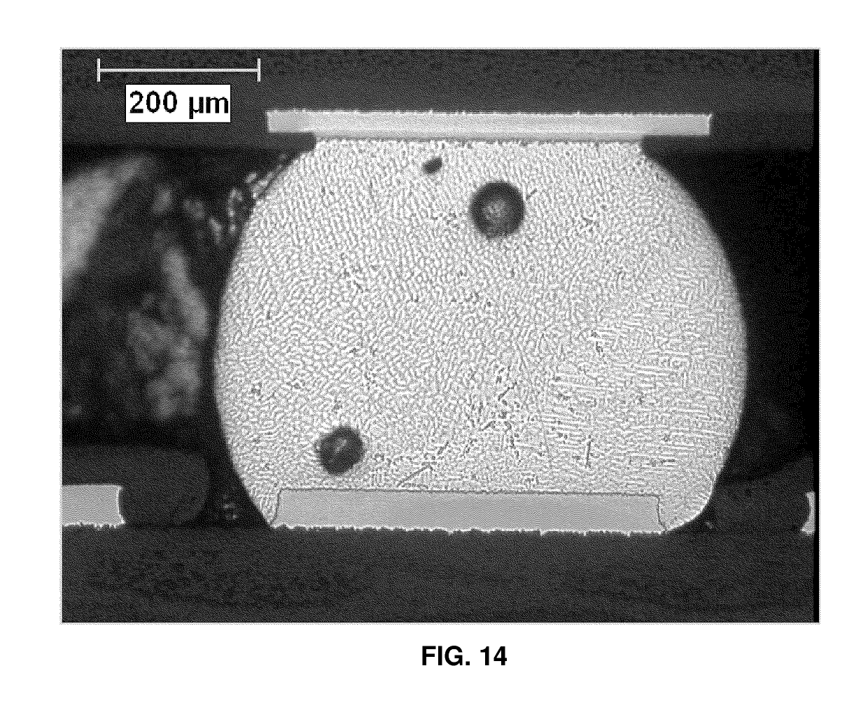

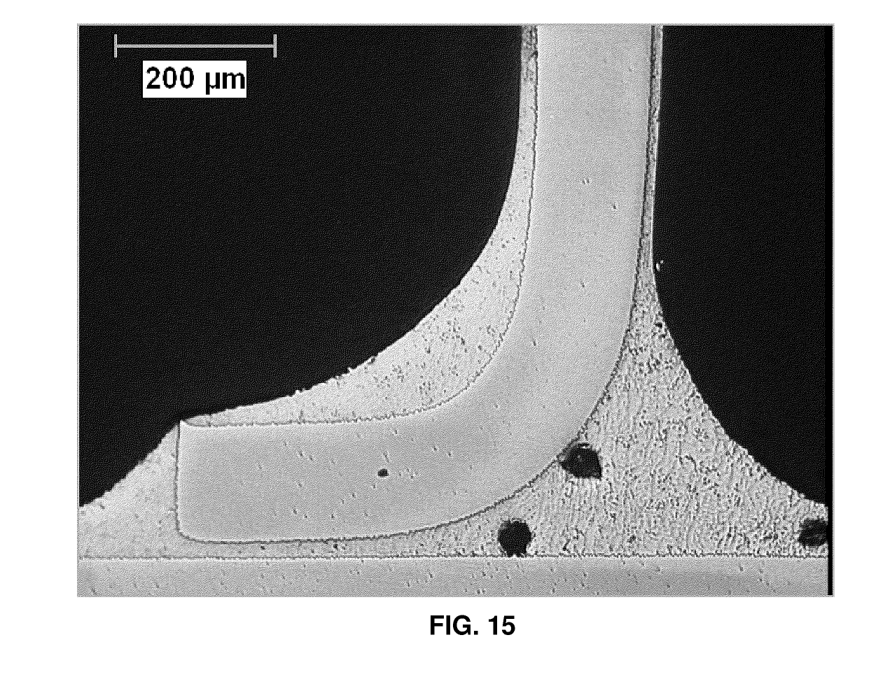

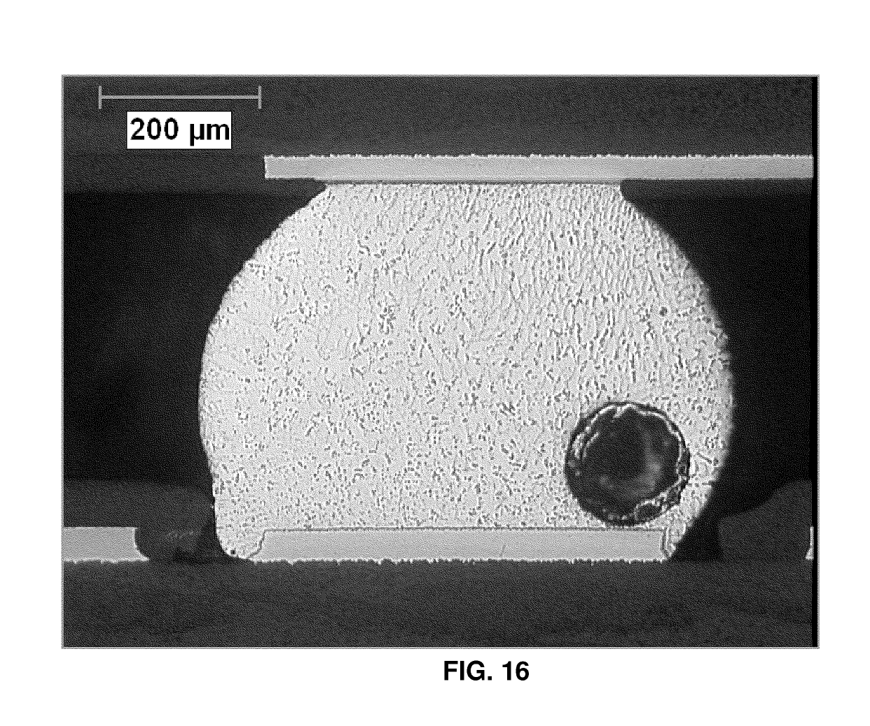

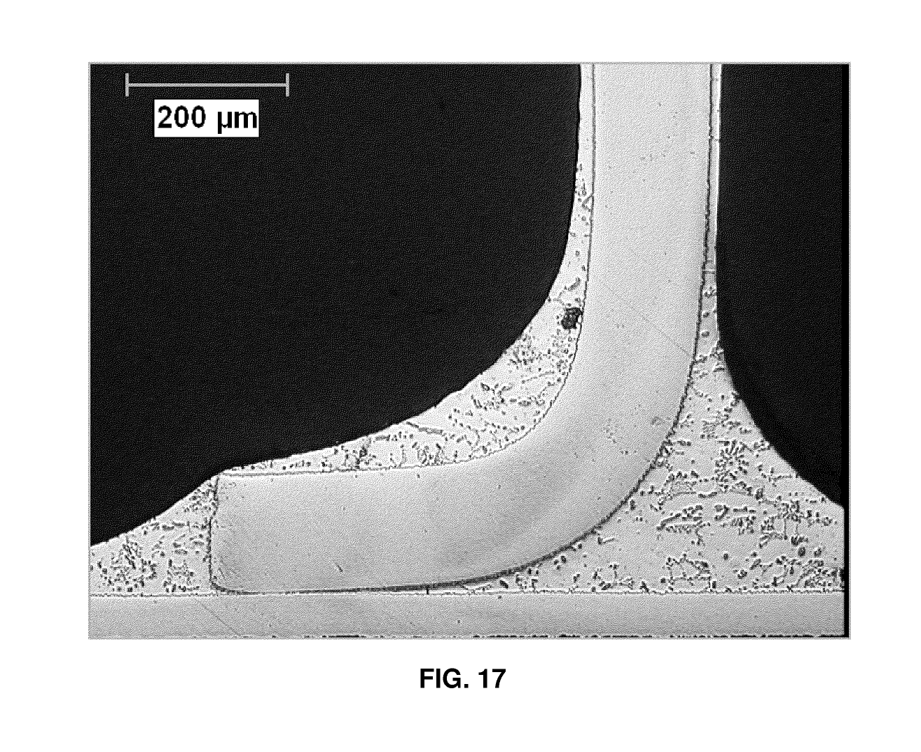

FIGS. 14 to 17 show metallurgical cross sections of various solder joints. These solder joints were generally formed by taking either a BGA having SAC 305 solder ball or a QFP lead and joining it to an OSP coated surface using a solder paste. Specifically, FIGS. 14 and 16 show BGA having SAC 305 solder balls being joined using SAC 305 solder paste and the solder paste of Example Composition 1, respectively. FIGS. 15 and 17 show QFP joints formed using SAC 305 solder paste and the solder paste of Example Composition A, respectively. It is noted that FIGS. 14 and 15 are shown as reference cross sections for comparison purposes.

Energy dispersive x-ray spectroscopy (EDXS) was used to infer the degree to which the SAC 305 solder balls were mixed with Example Composition A. Although the EDXS technique may be somewhat imprecise, the degree of mixing can be inferred by measuring a decrease in silver concentration of the SAC 305 solder ball after reflow. In a well-mixed joint, the balls of the samples comprising Example Composition A should have a lower silver concentration due to silver migration from the SAC 305 ball to the Example Composition A paste. In contrast, for the samples produced using SAC 305 solder paste, no change should be measured as there is no difference in silver content between the ball and the paste.

Using this method, the EDXS analysis of the cross section of FIG. 16 indicated that the SAC 305 solder balls were mixed with the bismuth-containing solder, as the bismuth concentration in FIG. 16 was found to be lower due to bismuth migration from the paste to the SAC 305 ball. As can be seen from Table 2 below, the silver concentration according to EDXS is lower for joints comprising Example Composition A in comparison with joints comprising SAC 305, given the same surface. Using the same method, it was also determined that the bismuth concentration in BGA joints formed using Example Composition A was less than about 2.1%. In the example BGA arrays, the solder joint comprised approximately 25 percent solder paste by volume and 75 percent solder ball by volume. According to the phase diagram, the bismuth concentration in the solder joints is close to the solubility of bismuth in tin at the reflow temperature. As such, precipitation of the bismuth component is not expected in the solder joints. The bismuth component in the solder joint may, however, provide solid-solution strengthening to the joint.

TABLE 2
Example Composition A and SAC 305 Solder Joint Compositions

| | | | | | | QFP Compo- |
|---|---|---|---|---|---|---|
| | Surface | BGA Composition (Wt. %) | | | | sition (Wt. %) |
| Solder Name | finish | Sn | Ag | Cu | Bi | Bi |
| SAC305 | OSP | 96.2 | 2.8 | 1.0 | 0 | 0 |
| Example | OSP | 95.7 | 2.1 | 0.7 | 1.5 | 3.8 |
| Composition A | | | | | | |
| SAC305 | ENIG | 96.7 | 2.8 | 0.5 | 0 | 0 |
| Example | ENIG | 95.5 | 2.2 | 0.6 | 1.7 | 3.7 |
| Composition A | | | | | | |
| Example | ENEPIG | 95.1 | 2.8 | 0.6 | 1.5 | 3.5 |
| Composition A | | | | | | |

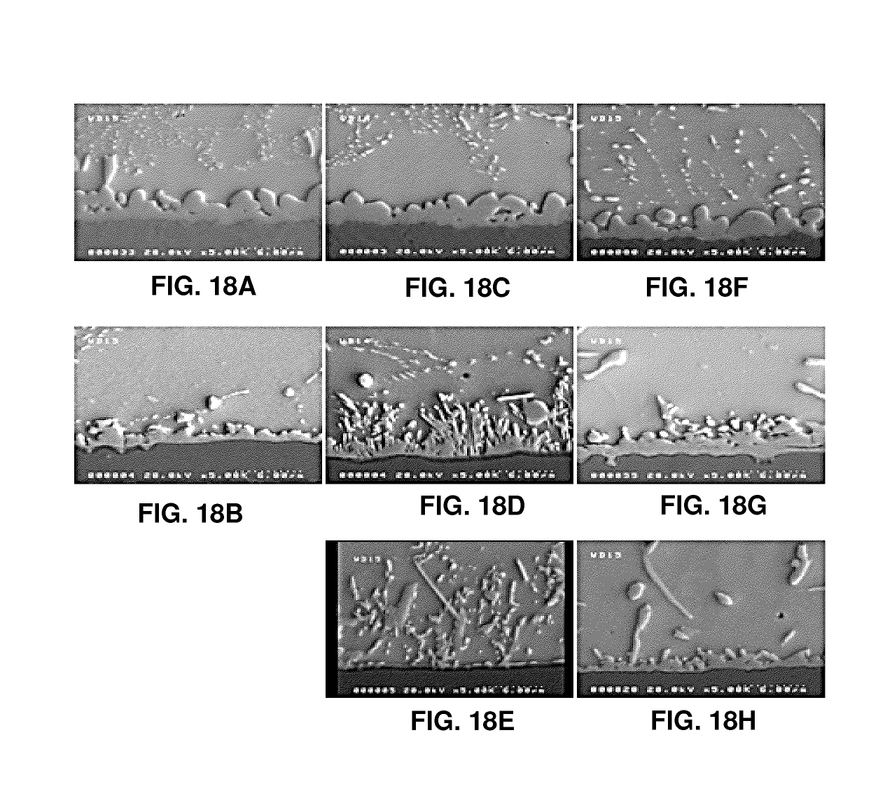

As mentioned above, the size and morphology of intermetallics affects the impact of these intermetallics on solder joints. FIGS. 18A and 18B show joints formed using a SAC 305 solder paste, FIGS. 18C through 18E show joints formed using Sn3.4% Ag4.8% Bi solder, and FIGS. 18F through 18H show joints formed using Example Composition A solder paste. Needle-like irregular intermetallic morphology in the joint may induce stress concentration and reduce reliability of solder joints. As can be seen from FIG. 18D and FIG. 18E, the Sn3.4% Ag4.8% Bi solder produces significant needle-like irregular intermetallics on ENIG and ENEPIG surfaces. Comparative example SAC 305 produces smoother intermetallics on ENIG surfaces, as is evidenced in FIG. 18B. Example Composition A produces relatively smooth and regular intermetallics on OSP, ENIG, and ENEPIG surfaces, as is evidenced in FIGS. 18F through 18H. Specifically, Example Composition A does not appear to produce needle-like irregular intermetallics on any of the three surface finishes.

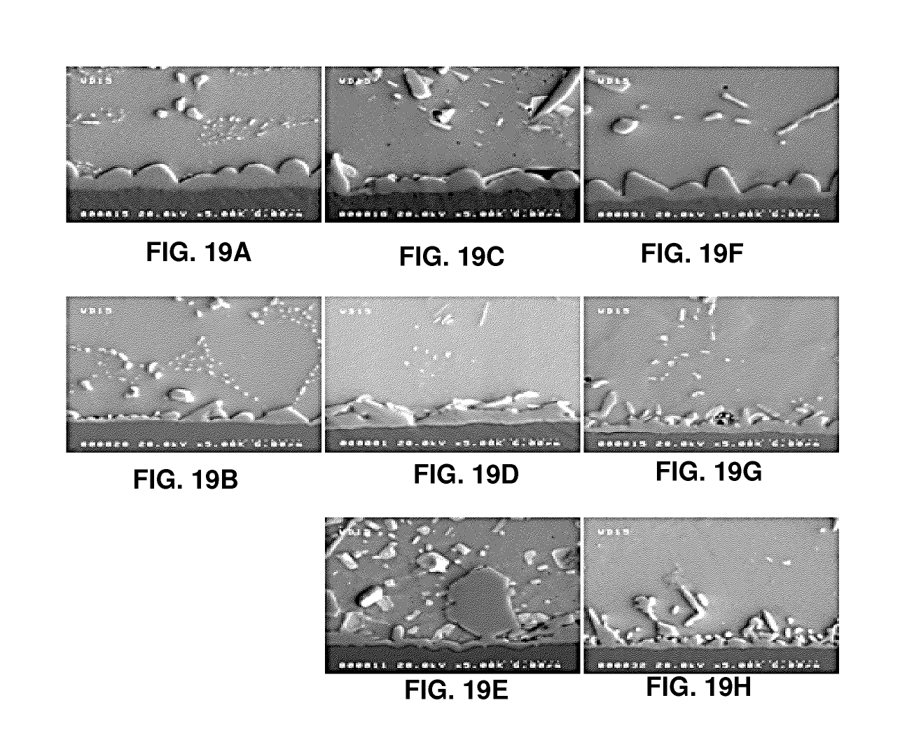

Similarly, FIGS. 19A through 19H show various QFP joints. FIGS. 19A and 19B show joints formed using a SAC 305 solder paste whereas FIGS. 19C through 19E show joints formed using Sn3.4% Ag4.8% Bi solder, and FIGS. 19F though 19H show joints formed using Example Composition A solder paste. As can be seen from FIG. 19D and FIG. 19E, the Sn3.4% Ag4.8% Bi solder produces large, irregular intermetallics on ENEPIG surfaces. Comparative example SAC 305 produces smoother intermetallics on OSP and ENIG surfaces, as is evidenced in FIGS. 19A and 19B. Example Composition A produces relatively smooth and regular intermetallics on OSP, ENIG, and ENEPIG surfaces, as is evidenced in FIGS. 19F through 19H. Specifically, Example Composition A does not appear to produce needle-like, irregular intermetallics on any of the three surface finishes. Further analysis related to the above solder compositions are presented in a paper by Snugovsky et al. (Polina Snugovsky et al. (2013); “Manufacturability and Reliability Screening of Lower Melting Point Pb-Free Alloys Containing Bi”, IPC APEX EXPO Conference, San Diego), which is incorporated herein by reference in its entirety.

Although the invention has been described with reference to certain specific embodiments, various modifications thereof will be apparent to those skilled in the art. Any examples provided herein are included solely for the purpose of illustrating the invention and are not intended to limit the invention in any way. Any drawings provided herein are solely for the purpose of illustrating various aspects of the invention and are not intended to be drawn to scale or to limit the invention in any way. The scope of the claims appended hereto should not be limited by the preferred embodiments set forth in the above description, but should be given the broadest interpretation consistent with the present specification as a whole. The disclosures of all prior art recited herein are incorporated herein by reference in their entirety.

We claim:

1. A solder composition comprising:
from about 5.5 to 7.0 percent by weight of bismuth;
from about 2.0 to 2.5 percent by weight of silver;
from about 0.5 to 0.7 percent by weight of copper; and
the remainder of the composition being tin.

2. The solder composition of claim 1 wherein the bismuth component is approximately equal to the silver component plus 7 times the copper component.

3. The solder composition of claim 1 wherein the bismuth component is approximately 6 percent.

4. The solder composition of any one of claims 1 to 3 wherein the copper component is approximately 0.5 percent.

5. The solder composition of any one of claims 1 to 4 wherein the silver component is approximately 2.25 percent.

6. The use of the solder composition of claim 1 for soldering a surface mount component.

7. The use of the solder composition according to claim 6, wherein the surface mount component is selected from a group consisting of a shrink small-outline package, a ball grid array, and a quad flat package.

8. The use of the composition according to claim 6 or 7 with a laminate circuit board.

9. The use of the composition according to claim 8, wherein the laminate circuit board is a Tg 140° C. laminate circuit board.

10. The use of the solder composition of claim 1 for soldering a ball grid array, wherein the amount of the solder composition used is greater than about 15% by volume of the solder balls of the ball grid array.

11. The use of the solder composition according to claim 10, wherein the amount of the solder composition used is greater than about 20% by volume of the solder balls of the ball grid array.

12. The use of the solder composition according to claim 10 or 11, wherein the solder balls of the ball grid array comprise SAC 305.

13. The use of the solder composition of claim 1 for soldering components onto a circuit board coated with an organic solderability protection or gold.

14. The solder composition of claim 1, wherein the pasty range of the solder is about 10° C.

15. An electronic device comprising the solder having the composition of claim 1.

16. A solder composition consisting essentially of:
from about 5.5 to 7.0 percent by weight of bismuth;
from about 2.0 to 2.5 percent by weight of silver;
from about 0.5 to 0.7 percent by weight of copper; and
the remainder of the composition being tin.
